(19) United States
(12) Patent Application Publication
(10) Pub. No.: US 2011/0014770 A1
(43) Pub. Date: Jan. 20, 2011

(54) Methods of forming a dielectric thin film of a semiconductor device and methods of manufacturing a capacitor having the same

(75) Inventors: Ki-yeon Park, Seoul (KR); Cha-young Yoo, Suwon-si (KR); Jong-cheol Lee, Seoul (KR); Jun-noh Lee, Hwaseong-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/591,722

(22) Filed: Nov. 30, 2009

(30) Foreign Application Priority Data
Jul. 14, 2009 (KR) 10-2009-0064085

(51) Int. Cl. H01G 9/00; H01L 21/469

(52) U.S. Cl. 438/381; 438/778; 257/E21.487

(57) ABSTRACT

A method of forming a dielectric thin film of a semiconductor device, the method including supplying a first nuclear atom precursor source and a second nuclear atom precursor source having different thermal decomposition temperatures to a substrate and forming a chemical adsorption layer including first nuclear atoms and second nuclear atoms on the substrate. A reactant including oxygen atoms may be supplied to the substrate on which the chemical adsorption layer is formed. An atomic layer including an oxide of the first nuclear atoms and the second nuclear atoms may be formed on the chemical adsorption layer.

### CROSS-REFERENCE TO RELATED APPLICATIONS

This application claims the benefit of priority under 35 U.S.C. §119 from Korean Patent Application No. 10-2009-0064085, filed on Jul. 14, 2009, in the Korean Intellectual Property Office, the disclosure of which is incorporated herein in its entirety by reference.

### BACKGROUND

1. FIELD

Example embodiments relate to methods of forming a thin film and methods of manufacturing a capacitor having the same. Other example embodiments relate to methods of forming a dielectric thin film of a semiconductor device.

2. Description of Related Art

As semiconductor memory devices become ultra-highly integrated, a design rule thereof gradually decreases, and the area of a unit memory cell in semiconductor memory devices decreases. In dynamic random access memory (DRAM) devices, even if the area of a capacitor used in a memory cell decreases, the minimum capacitance sufficient to provide a data input/output characteristic and a data reproduction characteristic needs to be provided. Due to such needs, a reduction in a process margin and space substantially affects the design of a memory cell capacitor.

In order to manufacture a capacitor that maintains minimum capacitance in a reduced space, various types of electrode structures disposed under a capacitor and having a three dimensional structure, as well as electrode structures having a large height have been suggested. In order to increase capacitance per unit area of a capacitor, various technologies for forming a dielectric film of a capacitor have been proposed. In order to obtain a dielectric film having increased electrical characteristics, a dielectric film having high purity (i.e., no impurities) is needed.

If a process temperature is increased when the dielectric film is deposited on the substrate, the diffusion of impurities into the dielectric film while the dielectric film is deposited on the substrate may be suppressed. If deposition temperature is increased so as to suppress diffusion of impurities when a dielectric film is formed on a substrate by using an atomic layer deposition (ALD) process, an undesired thermal decomposition phenomenon occurs between a source material (supplied to the substrate so as to form the dielectric film) and a chemical adsorption layer formed on the substrate by the source material. An undesired reaction may occur between the non-reactive source material and the chemical adsorption layer. As such, an ALD deposition mechanism (which is to be controlled) is destroyed due to a surface reaction between the source material and a reactant including oxygen atoms such that the linearity of a deposition speed (which is to be controlled) based on the atomic layer formed in each ALD cycle is not achieved, the thickness of the dielectric film is not precisely adjusted and/or a step coverage characteristic of the dielectric film deteriorates. In the case of a dielectric film deposited on a high-step stereoscopic structure having a substantially large aspect ratio, a leakage current characteristic of the dielectric film may deteriorate due to the deteriorated step coverage characteristic in which a uniformity of thickness of the dielectric film deteriorates according to a depth direction of a step.

### SUMMARY

Example embodiments relate to methods of forming a thin film and methods of manufacturing a capacitor having the same. Other example embodiments relate to methods of forming a dielectric thin film of a semiconductor device.

Example embodiments provide a method of forming a dielectric thin film of a semiconductor device, by which a uniformity of thickness of the dielectric thin film that may be deposited on a high-step stereoscopic structure having a substantially large aspect ratio even at a comparatively (or substantially) high deposition temperature so as to suppress diffusion of impurities, so that a step coverage characteristic of the dielectric thin film increases.

According to example embodiments, there is provided a method of forming a dielectric thin film of a semiconductor device, the method including supplying a first nuclear atom precursor source and a second nuclear atom precursor source having different thermal decomposition temperatures to a substrate, forming a chemical adsorption layer including first nuclear atoms and a second nuclear atoms on the substrate, supplying a reactant including oxygen atoms to the substrate on which the chemical adsorption layer is formed, and forming an atomic layer including an oxide of the first nuclear atoms and the second nuclear atoms.

Formation of the chemical adsorption layer may include simultaneously supplying the first nuclear atom precursor source and the second nuclear atom precursor source to the substrate.

The first nuclear atom precursor source may have a first thermal decomposition temperature, and the second nuclear atom precursor source may have a second thermal decomposition temperature that is higher than the first thermal decomposition temperature. Formation of the chemical adsorption layer may include first supplying the first nuclear atom precursor source to the substrate and then supplying the second nuclear atom precursor source to the substrate. The first nuclear atom precursor source and the second nuclear atom precursor may be supplied sequentially, and consecutively.

The chemical adsorption layer may include a first chemical adsorption layer including the first nuclear atoms contained in the first nuclear atom precursor source and a second chemical adsorption layer including the second nuclear atoms contained in the second nuclear atom precursor source.

The first nuclear atoms of the first nuclear atom precursor source and the second nuclear atoms of the second nuclear atom precursor source may be the same.

The first nuclear atoms of the first nuclear atom precursor source and the second nuclear atoms of the second nuclear atom precursor source may be different.

The method may include repeatedly performing the formation of the chemical adsorption layer and the formation of the atomic layer until a dielectric thin film is formed on the substrate to a desired thickness.

### BRIEF DESCRIPTION OF THE DRAWINGS

Example embodiments will be more clearly understood from the following detailed description taken in conjunction with the accompanying drawings in which:

FIG. 1 is a flowchart illustrating a method of forming a dielectric thin film according to example embodiments;

FIG. 2 is an gas pulsing diagram in a one process cycle circulated within a reaction chamber if a dielectric thin film is formed using an atomic layer deposition (ALD) process of the method illustrated in FIG. 1 according to example embodiments;

FIG. 3 is an gas pulsing diagram in a one process cycle circulated within a reaction chamber if a dielectric thin film is formed using an ALD process of the method illustrated in FIG. 1 according to example embodiments;

FIGS. 4A and 4B illustrate examples of mechanism in which two precursor source materials having different thermal decomposition temperatures and thus having different thermal decomposition characteristics are supplied to a substrate and are stably bonded to each other in the dielectric thin film using the method of FIG. 1;

FIGS. 5A through 5C are cross-sectional views illustrating a method of manufacturing a capacitor of a semiconductor memory device by using the method of forming a dielectric thin film of FIG. 1 according to example embodiments;

FIG. 6 is a graph showing a result of evaluating a leakage current characteristic of a ZrO₂ dielectric thin film formed by using a conventional method of forming a dielectric thin film according to temperatures that are appropriate for performing an ALD process;

FIG. 7 is a graph showing a result of evaluating a leakage current characteristic of a dielectric thin film of a zirconium (Zr) oxide film doped with silicon (Si) formed by the method of FIG. 1 according to temperatures that are appropriate for performing an ALD process;

FIG. 8 is a graph showing a result of comparing Comparative Examples of the thermal decomposition characteristic of a dielectric thin film formed by using the method of FIG. 1;

FIG. 9 is a graph showing a result of measuring performed by a thermogravimetric differential thermal analyzer (TG-DTA) so as to evaluate thermal decomposition characteristics of Zr precursors that may be used in the method of FIG. 1; and

FIG. 10 is a graph showing a result of measuring performed by a TG-DTA so as to evaluate thermal decomposition characteristics of Si precursors that may be used in the method of FIG. 1.

### DETAILED DESCRIPTION OF EXAMPLE EMBODIMENTS

Various example embodiments will now be described more fully with reference to the accompanying drawings in which some example embodiments are shown. However, specific structural and functional details disclosed herein are merely representative for purposes of describing example embodiments. Thus, the invention may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the invention.

In the drawings, the thicknesses of layers and regions may be exaggerated for clarity, and like numbers refer to like elements throughout the description of the figures.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that, if an element is referred to as being “connected” or “coupled” to another element, it can be directly connected, or coupled, to the other element or intervening elements may be present. In contrast, if an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” if used herein, specify the presence of stated features, integers, steps, operations, elements and/or components, but do not preclude the presence or addition of one or more other features, integers, steps, operations, elements, components and/or groups thereof.

Spatially relative terms (e.g., “beneath,” “below,” “lower,” “above,” “upper” and the like) may be used herein for ease of description to describe one element or a relationship between a feature and another element or feature as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments, various aspects will be described in detail with reference to the attached drawings. However, the present invention is not limited to example embodiments described

Example embodiments relate to methods of forming a thin film and methods of manufacturing a capacitor having the same. Other example embodiments relate to methods of forming a dielectric thin film of a semiconductor device.

A method of forming a dielectric thin film to manufacture a semiconductor device by using an atomic layer deposition (ALD) process according to example embodiments provides the dielectric thin film in which thermal decomposition of a precursor used as a source material for forming the dielectric thin film is suppressed, the amount of impurities in the dielectric thin film to be formed decreases, a step coating characteristic increases and/or an electrical characteristic increases.

In example embodiments, in order to form a high quality dielectric thin film in which diffusion of impurities is suppressed, a plurality of precursors having different thermal decomposition temperatures are supplied to a substrate, and a chemical adsorption layer is formed on the substrate.

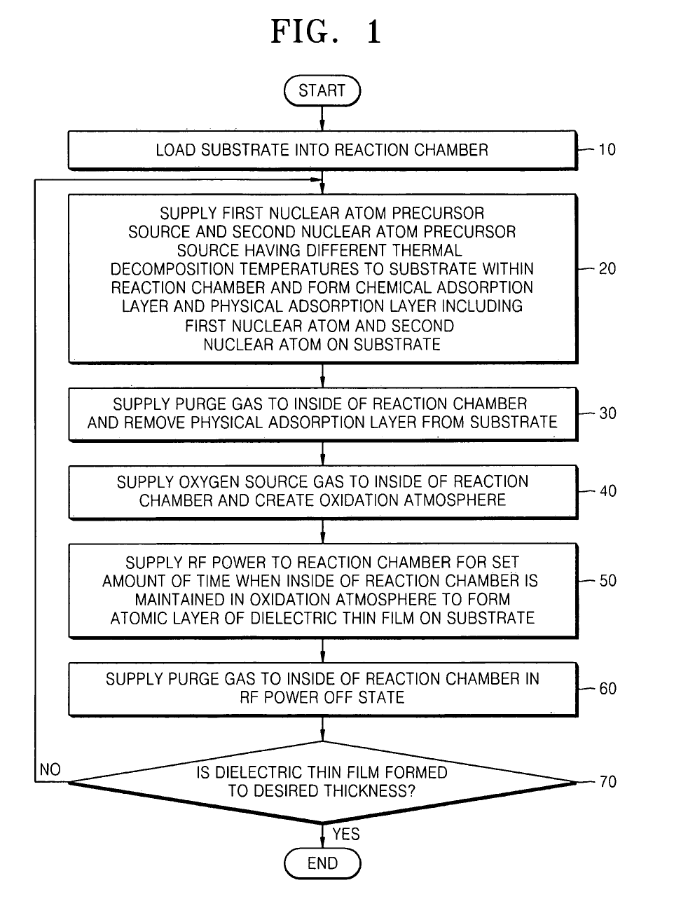

FIG. 1 is a flowchart illustrating a method of forming a dielectric thin film according to example embodiments.

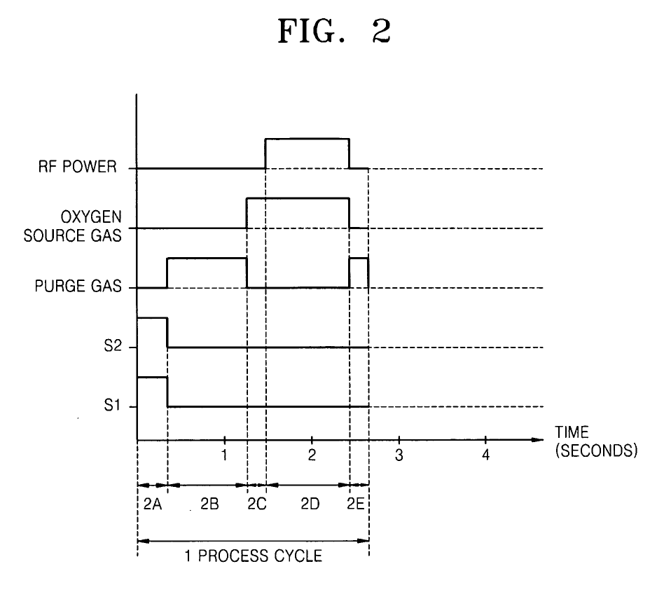

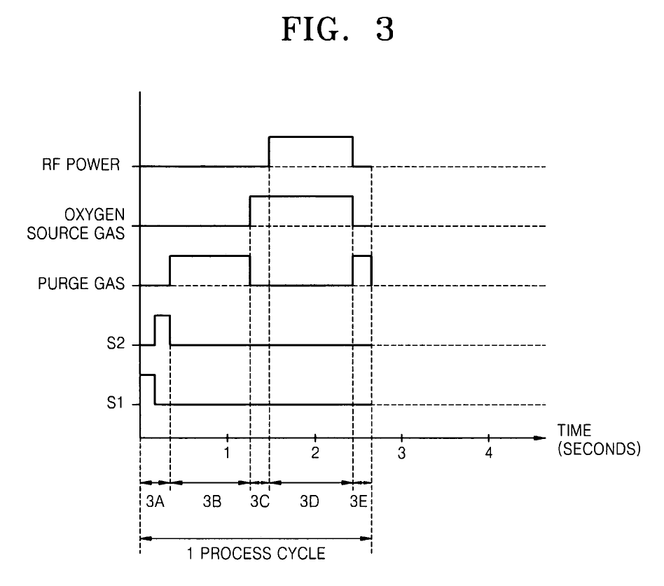

FIGS. 2 and 3 are respectively gas pulsing diagrams in a one process cycle circulated within a reaction chamber when a dielectric thin film is formed using an ALD process of the method illustrated in FIG. 1 according to example embodiments.

The method of forming a dielectric thin film according to example embodiments will now be described in detail with reference to FIGS. 1 and 2.

A substrate is loaded into a reaction chamber in which an ALD process is to be performed (Operation 10). The temperature of the substrate in the reaction chamber may be selected in various ranges according to the type of dielectric thin film to be formed. For example, the substrate may be controlled to be maintained at a set temperature that is selected in a range of about 100° C. to about 550° C. Atmospheric pressure in the reaction chamber may be maintained within about 0.1-torr to about 10-torr.

A first nuclear atom precursor source S1 and a second nuclear atom precursor source S2 having different thermal decomposition temperatures are supplied to the substrate, thereby forming a chemical adsorption layer and a physical adsorption layer including the first nuclear atom precursor source S1 and the second nuclear atom precursor source S2 (Operation 20 of FIG. 1, Operation “2A” of FIG. 2 or Operation “3A” of FIG. 3).

If the first nuclear atom precursor source S1 and the second nuclear atom precursor source S2 are supplied to the substrate, the first nuclear atom precursor source S1 and the second nuclear atom precursor source S2 may be simultaneously supplied to the substrate, as illustrated in FIG. 2.

Alternatively, after one of the first nuclear atom precursor source S1 and the second nuclear atom precursor source S2, having a relatively low thermal decomposition temperature, is first supplied to the substrate, the other one having a relatively high thermal decomposition temperature may be supplied to the substrate. For example, if the first nuclear atom precursor source S1 has a first thermal decomposition temperature T1 and the second nuclear atom precursor source S2 has a second thermal decomposition temperature T2 that is higher than the first thermal decomposition temperature T1 (i.e., T1<T2), as illustrated in FIG. 3. After the first nuclear atom precursor source S1 is first supplied to the substrate, the second nuclear atom precursor source S2 may be then supplied to the substrate. The second nuclear atom precursor source S2 may be sequentially, and consecutively, supplied to the substrate after the first nuclear atom precursor S1.

The chemical adsorption layer, which is obtained by simultaneously, or sequentially, supplying the first nuclear atom precursor source S1 and the second nuclear atom precursor source S2 to the substrate, as illustrated in FIGS. 2 and 3, may include a first chemical adsorption layer including first nuclear atoms M1 contained in the first nuclear atom precursor source S1 and a second chemical adsorption layer disposed on the first chemical adsorption layer to be chemically bonded thereto and including second nuclear atoms M2 contained in the second nuclear atom precursor source S2.

If necessary, the first nuclear atoms M1 of the first nuclear atom precursor source S1 having a relatively low thermal decomposition temperature and the second nuclear atoms M2 of the second nuclear atom precursor source S2 having a relatively high thermal decomposition temperature may be the same, or different, from each other. If the first nuclear atoms M1 and the second nuclear atoms M2 are different elements, a flow amount of the second nuclear atom precursor source S2 being supplied to the substrate is not greater than that of the first nuclear atom precursor S1.

If the first nuclear atoms M1 and the second nuclear atoms M2 are the same, each of the first nuclear atoms M1 and the second nuclear atoms M2 may be one selected from the group consisting of zirconium (Zr), hafnium (Hf), titanium (Ti), lanthanum (La), silicon (Si) and combinations thereof. Alternatively, for example, if the first nuclear atoms M1 and the second nuclear atoms M2 are different elements, the first nuclear atoms M1 may be one selected from the group consisting of Zr, Hf, Ti, La and combinations thereof, and the second nuclear atoms M2 may be one selected from the group consisting of Si, Ti and combinations thereof.

If the first nuclear atoms M1 and the second nuclear atoms M2 are the same elements, the dielectric thin film that is finally obtained by using the method of FIG. 1 may be an oxide film having single nuclear atoms. In other words, a Zr oxide film, an Hf oxide film, a Ti oxide film, or a La oxide film may be formed by using the method of FIG. 1.

If the dielectric thin film is formed as a Zr oxide film by using the method of FIG. 1, each of the first nuclear atom precursor source S1 and the second nuclear atom precursor source S2 may be a precursor source including Zr nuclear atoms. In particular, tetrakis(ethylmethylamino)zirconium (TEMAZ) having a relatively low thermal decomposition temperature may be used as the first nuclear atom precursor source S1, and zirconium (IV) t-butoxide (ZTTB), Zr(MMP)₄ (MMP=1-methoxy-2-methyl-2-propionate), Zr(DMAMP)₄ (DMAMP=1-dimethylamino-2-methyl-2-propanolate), Zr(METHD)₄ (METHD=methoxyethoxytetramethylheptanedione), or Zr(THD)₄ (THD=tetramethylheptanedione) having a relatively high thermal decomposition temperature may be used as the second nuclear atom precursor source S2.

If the dielectric thin film is formed as an Hf oxide film by using the method of FIG. 1, each of the first nuclear atom precursor source S1 and the second nuclear atom precursor source S2 may be a precursor source including Hf nuclear atoms. In particular, tetrakis(ethylmethylamino)hafnium (TEMAH) having a relatively low thermal decomposition temperature may be used as the first nuclear atom precursor source S1, and tBH (Hf(OC₄H₉)₄), Hf(MMP)₄ (MMP=1-methoxy-2-methyl-2-propionate), Hf(DMAMP)₄ (DMAMP=1-dimethylamino-2-methyl-2-propanolate), Hf(METHD)₄ (METHD=methoxyethoxytetramethylheptanedione), or Hf(THD)₄ (THD=tetramethylheptanedione) having a relatively high thermal decomposition temperature may be used as the second nuclear atom precursor source S2.

If the dielectric thin film is formed as a Ti oxide film by using the method of FIG. 1, each of the first nuclear atom precursor source S1 and the second nuclear atom precursor source S2 may be a precursor source including Ti nuclear atoms. In particular, tetrakis(ethylmethylamino)titanium (TEMAT), tetrakis(dimethylamido)titanium (TDMAT), or Ti(OiPr)₂(THD)₂ (OiPr=isopropoxide (—OCH(CH₃)₂)) having a relatively low thermal decomposition temperature may be used as the first nuclear atom precursor source S1, and Ti(MMP)₄, titanium tetratertbutoxide (TTTB), Ti(MPD)(THD)₂ (MPD=methylpentanedione, THD=tetramethylheptanedione), or titanium tetraisopropyltitanate (TIPT) having a relatively high thermal decomposition temperature may be used as the second nuclear atom precursor source S2.

If the dielectric thin film is formed as a La oxide film by using the method of FIG. 1, each of the first nuclear atom precursor source S1 and the second nuclear atom precursor source S2 may be a precursor source including La nuclear atoms. In particular, La(EDMDD)₃ (tris(6-ethyl-2,2-dimethyl-3,5-decanedionato)lanthanum (III)) having a relatively low thermal decomposition temperature may be used as the first nuclear atom precursor source S1, and La(sBuCp)₃ (sBuCp=sec-butyl-cyclopentadiene: C₅H₅CH(CH₃(CH₂CH₃))), La(iPrCp)₃ (tris(i-propylcyclopentadienyl)lanthanum), or La(THD)₃ having a relatively high thermal decomposition temperature may be used as the second nuclear atom precursor source S2.

If the first nuclear atoms M1 and the second nuclear atoms M2 are different elements, the dielectric thin film that is finally obtained by using the method of FIG. 1 may be formed as an oxide film of the first nuclear atoms M1 doped with the second nuclear atoms M2. In other words, a Zr oxide film doped with Si, a Zr oxide film doped with Ti, an Hf oxide film doped with Si, an Hf oxide film doped with Ti, a Ti oxide film doped with Si or a La oxide film doped with Si may be obtained by using the method of FIG. 1.

If a Zr oxide film doped with Si is formed by using the method of FIG. 1, a precursor source including Zr nuclear atoms may be used as the first nuclear atom precursor source S1, and a precursor source including Si nuclear atoms may be used as the second nuclear atom precursor source S2. For example, TEMAZ or tetrakis (2-methyl-3-butene-2-oxy) zirconium (ZMBO) having a relatively low thermal decomposition temperature may be used as the first nuclear atom precursor source S1, and trisdimethylamidosilane (3DMAS), tetrakisdimethylaminosilane (4DMAS), tris(ethylmethylamino) silane (TEMASiH), tetraethylorthosilicate (TEOS), hexachlorodisilane (HCD), TICS (Si(NCO)₄), or tris ethyl methyl amino silane (3EMAS) having a relatively high thermal decomposition temperature may be used as the second nuclear atom precursor source S2.

If a Zr oxide film doped with Ti is formed by using the method of FIG. 1, a precursor source including Zr nuclear atoms may be used as the first nuclear atom precursor source S1, and a precursor source including Ti nuclear atoms may be used as the second nuclear atom precursor source S2. For example, TEMAZ having a relatively low thermal decomposition temperature may be used as the first nuclear atom precursor source S1, and TEMAT, TDMAT, Ti(OiPr)₂(THD)₂, Ti(MMP)₄, TTTB, Ti(MPD)(THD)₂, or TIPT having a relatively high thermal decomposition temperature may be used as the second nuclear atom precursor source S2.

If an Hf oxide film doped with Si is formed by using the method of FIG. 1, a precursor source including Hf nuclear atoms may be used as the first nuclear atom precursor source S1, and a precursor source including Si nuclear atoms may be used as the second nuclear atom precursor source S2. For example, TEMAH having a relatively low thermal decomposition temperature may be used as the first nuclear atom precursor source S1, and 3DMAS, 4DMAS, TEMASiH, TEOS, HCD, or TICS having a relatively high thermal decomposition temperature may be used as the second nuclear atom precursor source S2.

If an Hf oxide film doped with Ti is formed by using the method of FIG. 1, a precursor source including Hf nuclear atoms may be used as the first nuclear atom precursor source S1, and a precursor source including Ti nuclear atoms may be used as the second nuclear atom precursor source S2. For example, TEMAH having a relatively low thermal decomposition temperature may be used as the first nuclear atom precursor source S1, and TEMAT, TDMAT, Ti(OiPr)₂(THD)₂, Ti(MMP)₄, TTTB, Ti(MPD)(THD)₂, or TIPT having a relatively high thermal decomposition temperature may be used as the nuclear atom precursor source S2.

If a Ti oxide film doped with Si is formed by using the method of FIG. 1, a precursor source including Ti nuclear atoms may be used as the first nuclear atom precursor source S1, and a precursor source including Si nuclear atoms may be used as the second nuclear atom precursor source S2. For example, TIPT having a relatively low thermal decomposition temperature may be used as the first nuclear atom precursor source S1, and 3DMAS, 4DMAS, TEMASiH, TEOS, HCD, or TICS having a relatively high thermal decomposition temperature may be used as the second nuclear atom precursor source S2.

If a La oxide film doped with Si is formed by using the method of FIG. 1, a precursor source including La nuclear atoms may be used as the first nuclear atom precursor source S1, and a precursor source including S1 nuclear atoms may be used as the second nuclear atom precursor source S2. For example, La(EDMDD)₃, La(sBuCp)₃, La(iPrCp)₃, or LA(THD)₃ having a relatively high thermal decomposition temperature may be used as the first nuclear atom precursor source S1, and 3DMAS, 4DMAS, TEMASiH, TEOS, HCD, or TICS having a relatively high thermal decomposition temperature may be used as the second nuclear atom precursor source S2.

As described above, if the first nuclear atom precursor source S1 and the second nuclear atom precursor source S2 are simultaneously or sequentially supplied to the substrate, the chemical adsorption layer including the first chemical adsorption layer having the first nuclear atoms M1 contained in the first nuclear atom precursor source S1 and the second chemical adsorption layer having the second nuclear atoms M2 contained in the second nuclear atom precursor source S2, and the physical adsorption layer including a non-reactive material of the first nuclear atom precursor source S1 and the second nuclear atom precursor source S2 are formed (Operation 20 of FIG. 1, Operation “2A” of FIG. 2 or Operation “3A” of FIG. 3).

A purge gas is supplied to the inside of the reaction chamber, and the physical adsorption layer disposed on the substrate is separated and removed from the substrate (Operation 30 of FIG. 1, Operation “2B” of FIG. 2 or Operation “3B” of FIG. 3).

An inert gas such as argon (Ar) may be used as the purge gas.

An oxygen source gas is supplied to the inside of the reaction chamber if the chemical adsorption layer remains on a top surface of the substrate, and an oxidation atmosphere is created in the reaction chamber (Operation 40 of FIG. 1, Operation “2C” of FIG. 2 or Operation “3C” of FIG. 3).

At least one gas selected from the group consisting of H₂O, H₂O₂, O₃, O₂, N₂O and combinations thereof may be used as the oxygen source gas. Also, in order to control an oxidation force generated due to the oxygen source gas, if necessary, at least one gas selected from the group consisting of NH₃, N₂ gases and combinations thereof and the oxygen source gas may be supplied to the inside of the reaction chamber.

A radio frequency (RF) power is supplied to the reaction chamber for a set amount of time when the inside of the reaction chamber is maintained in an oxidation atmosphere, and a plasma of an atmospheric gas is generated in the reaction chamber (Operation 50 of FIG. 1, Operation “2D” of FIG. 2 or Operation “3D” of FIG. 3).

A plasma atmosphere is maintained in the reaction chamber, and the first nuclear atoms M1 and the second nuclear atoms M2 that have been chemically absorbed into the substrate react with a radical or ions of the atmospheric gas so that an atomic layer of a dielectric thin film is formed on the substrate.

The RF power for generating plasma may be set at about 50-W to about 1000-W, for example, about 100-W to about 400-W. A length of time an RF power may be maintained may be for about 0.1-seconds to about 10-seconds.

The purge gas is supplied to the inside of the reaction chamber in an RF power off state so that unnecessary materials such as non-reactive residuals and radicals that remain in the reaction chamber are discharged to the outside of the reaction chamber (Operation 60 of FIG. 1, Operation “2E” of FIG. 2 or Operation “3E” of FIG. 3).

It is determined whether a dielectric thin film is formed on the substrate to a desired thickness (Operation 70 of FIG. 1). If the desired thickness is not obtained, Operations 20 through 60 (i.e., one process cycle of FIG. 2 or 3) are repeatedly performed until the dielectric thin film is formed on the substrate to the desired thickness.

The time required for one process cycle shown in FIG. 2 or 3 may be about 10 seconds to 50 seconds. The process temperature in the reaction chamber while Operations 20 through 60 are repeatedly performed may be maintained at about 100° C. to 550° C.

As described above with reference to FIGS. 1 through 3, in the method of forming the dielectric thin film illustrated in FIG. 1, the first nuclear atom precursor source S1 and the second nuclear atom precursor source S2 that have different thermal decomposition temperatures are supplied to the substrate, thereby forming the chemical adsorption layer including the first nuclear atoms M1 and the second nuclear atoms M2 on the substrate so that a thermal decomposition characteristic of a raw material source may increase. In this way, the thermal decomposition characteristic of the raw material source increases so that a step coverage characteristic of the dielectric thin film, which is obtained as a resultant product, may not be deteriorated and a process temperature may be increased to about 50° C. compared to a conventional process temperature.

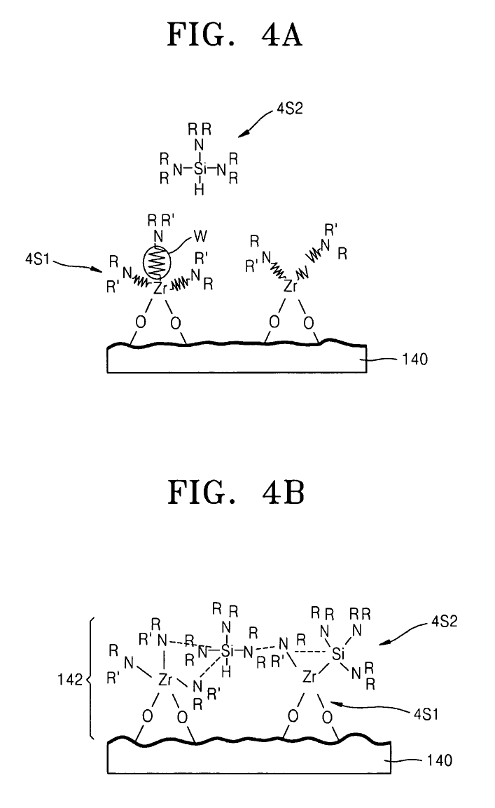

FIGS. 4A and 4B illustrate examples of mechanism in which two precursor source materials having different thermal decomposition temperatures and thus having different thermal decomposition characteristics are supplied to a substrate and are stably bonded to each other in the dielectric thin film using the method of FIG. 1.

In other words, FIGS. 4A and 4B illustrates the case that a first precursor source 4S1 having Zr nuclear atoms as a first nuclear atom precursor source having a relatively low thermal decomposition temperature is supplied to a substrate 140 and then a second precursor source 4S2 having Si nuclear atoms as a second nuclear atom precursor source is supplied to the substrate 140.

In FIG. 4A, the first precursor source 4S1 having a relatively low thermal decomposition temperature is weakly bonded to the second precursor source 4S2 due to a relatively high process temperature, as shown in parts marked by “W”. If the first precursor source 4S1 is thermally decomposed in the weakly-bonded state, an ALD deposition mechanism to be controlled may be destroyed due to a surface reaction of a source and an oxygen source gas. However, if the second precursor source 4S2 having a higher thermal decomposition temperature than that of the first precursor source 4S1 is supplied to a chemical adsorption layer of the first precursor source 4S1 (like in the method of forming the dielectric thin film of FIG. 1), the second precursor source 4S2 having a relatively strong thermal decomposition characteristic is bonded to the first precursor source 4S1 in the weakly-bonded parts (“W” parts) of the first precursor source 4S1 having a relatively weak thermal decomposition characteristic, and a chemically and stably bonded state is achieved as illustrated in FIG. 4B. As such, source molecules that remain in the reaction chamber in a non-reactive state are prevented from being additionally bonded to a chemical adsorption layer 142, and the thermal decomposition characteristic of the chemical adsorption layer 142 on an underlying layer (substrate) 140 increases. Here, ligands of molecules of the second precursor source 4S2 having a strong thermal decomposition characteristic may be removed by using a reactant formed of an oxygen source gas (e.g., H₂O or O₃) that is injected after the second precursor source 4S2 is supplied to the substrate 140.

As described above, the dielectric thin film is formed by the method of FIG. 1 so that a process of depositing the dielectric thin film is controlled by the surface reaction caused by the reactant formed of an oxygen source gas. The uniformity of thickness, or composition, of the dielectric thin film (that may be destroyed by thermal decomposition of a precursor source including nuclear atoms) may be reduced, or prevented. Problems such as generation of particles due to gas phase reaction during an ALD process and deterioration of the step coverage characteristics of the dielectric thin film may also be reduced, or prevented.

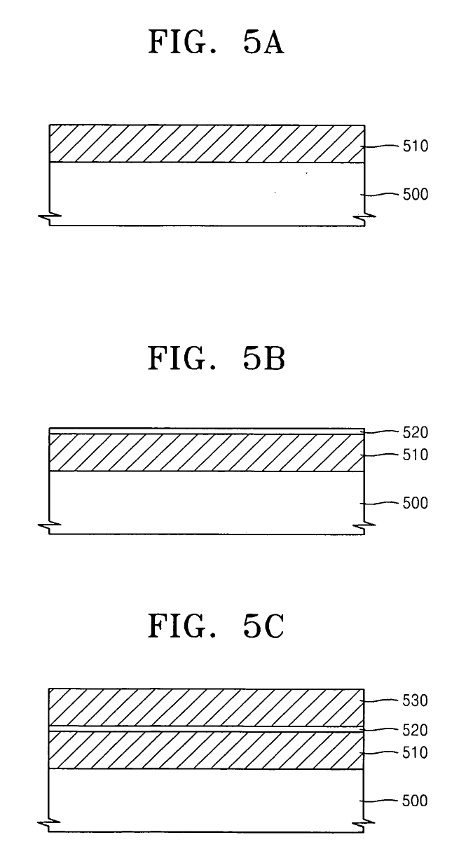

FIGS. 5A through 5C are cross-sectional views illustrating a method of manufacturing a capacitor of a semiconductor memory device by using the method of forming a dielectric thin film of FIG. 1 according to example embodiments.

Referring to FIG. 5A, a conductive material is deposited on a semiconductor substrate 500, forming a lower electrode 510 on the semiconductor substrate 500.

The lower electrode 510 may be formed of doped polysilicon, a metal, a metal nitride, a noble metal or combinations thereof. For example, the lower electrode 510 may be formed of TiN, TaN, WN, ruthenium (Ru), iridium (Ir) or platinum (Pt). The lower electrode 510 may be formed by using ALD, chemical vapor deposition (CVD), metal-organic CVD (MOCVD) or physical vapor deposition (PVD).

Referring to FIG. 5B, a dielectric thin film 520 is formed on the lower electrode 510. The dielectric thin film 520 may be formed by using the method described with reference to either of FIGS. 1 through 3.

The dielectric thin film 520 may be formed as a Zr oxide film, an Hf oxide film, a Ti oxide film or a La oxide film, for example. Alternatively, the dielectric thin film 520 may be formed as a Zr oxide film doped with Si, a Zr oxide film doped with Ti, an Hf oxide film doped with Si, an Hf oxide film doped with Ti, a Ti oxide film doped with Si or a La oxide film doped with Si.

After the dielectric thin film 520 is formed, a heat treatment process or a plasma treatment process for crystallizing the dielectric thin film 520 may be performed if necessary. The heat treatment process or the plasma treatment process may be performed at a relatively low temperature of about 250° C. to 450° C. For example, the heat treatment process or the plasma treatment process may be performed at a temperature of about 350° C. to 450° C. The heat treatment process, or plasma treatment process, for crystallizing the dielectric thin film 520 may be performed in a nitrogen-containing gas atmosphere including at least one selected from the group consisting of NH₃, N₂O, N₂ gas and combinations thereof.

Referring to FIG. 5C, an upper electrode 530 is formed on the dielectric thin film 520. The upper electrode 530 may be formed of doped polysilicon, a metal, a metal nitride or a noble metal. For example, the upper electrode 530 may be formed of TiN, TaN, WN, Ru, Ir, Pt or combinations thereof. The upper electrode 530 may be formed by using ALD, CVD, MOCVD or PVD.

### Evaluative Example 1

A cylinder type capacitor having an aspect ratio of 20:1 was formed so as to show the effect of increasing the characteristic of a dielectric thin film by suppressing thermal decomposition in the dielectric thin film formed by the method of FIG. 1. Here, an ALD process was used to form the dielectric thin film of the cylinder type capacitor, and a leakage current characteristic of each capacitor including a dielectric thin film that was obtained at temperatures that are appropriate for performing an ALD process was evaluated.

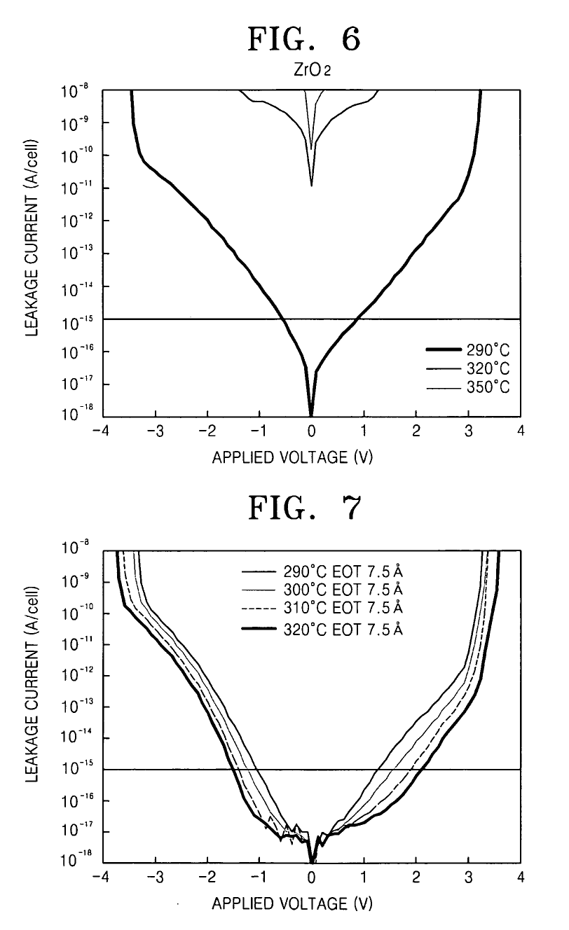

FIG. 6 is a graph showing a result of evaluating a leakage current characteristic of a ZrO₂ dielectric thin film formed by using a conventional method of forming a dielectric thin film according to temperatures that are appropriate for performing an ALD process.

For the evaluation, the result of which is shown in FIG. 6, in three cases that an ALD process temperature was set as 290° C., 320° C., and 350° C., respectively, the ZrO₂ dielectric thin film was formed by using a single precursor source having Zr nuclear atoms by performing a conventional method of forming a dielectric thin film and the leakage current characteristic of the ZrO₂ dielectric thin film that was obtained in each of the three cases was evaluated.

According to the result shown in FIG. 6, if the ALD process temperature was increased so as to increase the characteristic of the ZrO₂ dielectric thin film by reducing impurities in the ZrO₂ dielectric thin film, the leakage current characteristic of the ZrO₂ dielectric thin film was deteriorated by thermal decomposition of TEMAZ that was a Zr precursor source.

FIG. 7 is a graph showing a result of evaluating a leakage current characteristic of a dielectric thin film of a Zr oxide film doped with Si formed by the method of FIG. 1 according to temperatures that are appropriate for performing an ALD process.

For the evaluation, the result of which is shown in FIG. 7, the dielectric thin film formed as the Zr oxide film doped with Si was formed by performing a process of supplying TEMAZ that was a Zr precursor source having Zr nuclear atoms to a substrate and then performing a process of supplying a small amount of 3DMAS source having a higher thermal decomposition temperature than that of TEMAZ to the substrate source, by using the method of FIG. 1. The leakage current characteristic of the dielectric thin film formed as the Zr oxide film doped with Si was evaluated.

According to the result of FIG. 7, in the case of the Zr oxide film doped with Si that was deposited on the substrate by performing the process of supplying TEMAZ to the substrate and then by the process of supplying the small amount of 3DMAS as an Si precursor source having a higher thermal decomposition temperature than that of TEMAZ to the substrate, even though a deposition temperature was increased, the leakage current characteristic of the dielectric thin film was not deteriorated but increased. Also, the thermal decomposition characteristic of the dielectric thin film increased so that non-uniformity of the thickness and composition of the dielectric thin film that may occur due to the unstable bonded state in a chemical adsorption layer (that was obtained from the Zr precursor source when the dielectric thin film was deposited on the substrate), and generation of particles due to the gas phase reaction of a precursor source, were remarkably suppressed. As the deposition temperature was increased, diffusion of impurities in the dielectric thin film was suppressed. Even if an equivalent oxide thickness (EOT) was slightly increased due to the increased deposition temperature, the leakage current characteristic of the dielectric thin film increased by about 50% or more based on a voltage that satisfies 1 fA/cell at a high deposition temperature.

### Evaluative Example 2

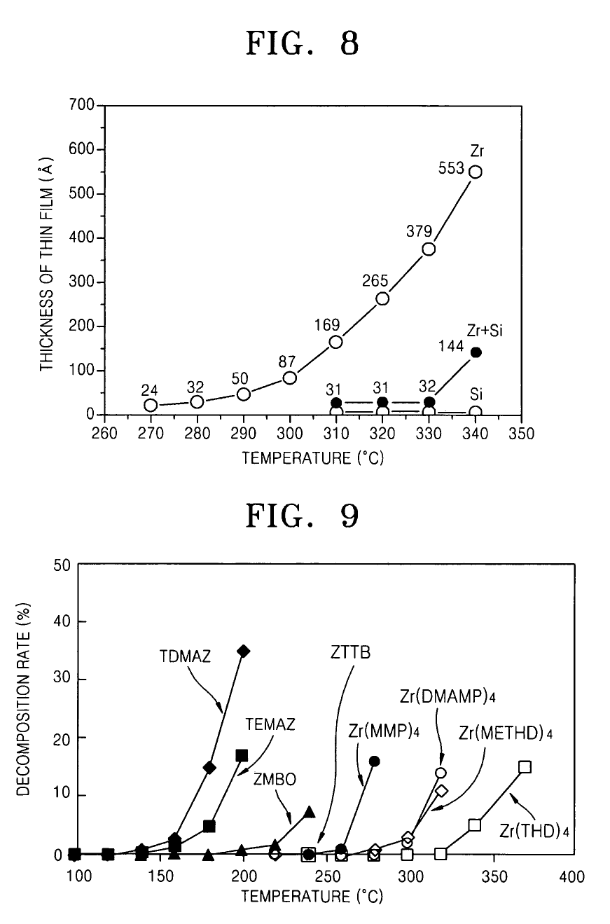

FIG. 8 is a graph showing the result of comparing Comparative Examples of a thermal decomposition characteristic of a dielectric thin film formed by using the method of FIG. 1.

Referring to the comparison result shown in FIG. 8, in order to form the dielectric thin film by using the method of FIG. 1, a first nuclear atom precursor source and a second nuclear atom precursor source having different thermal decomposition temperatures were supplied to a substrate, forming a chemical adsorption layer including first nuclear atoms and second nuclear atoms on the substrate. In this case, in order to show the effect of increasing the thermal decomposition characteristic of the dielectric thin film, a process of sequentially supplying a source gas (e.g., TEMAZ and 3DMAS) without supplying a reactant formed of an oxygen source gas, and a purging process using an inert gas, were repeatedly performed. In this case, in order to determine whether or not thermal deposition is performed due to thermal decomposition of the dielectric thin film (indicated by “Zr+Si” in FIG. 8), the deposition thickness of the dielectric thin film was measured according to a deposition temperature.

As a Comparative Example, the results of measuring the deposition thickness of the dielectric thin film according to the decomposition temperature, in the case where the dielectric thin film (indicated by “Zr” in FIG. 8) were obtained by repeatedly performing the process of supplying TEMAZ as a Zr precursor source to the substrate and the purging process and in the case where the dielectric thin film (indicated by “Si” in FIG. 8) was obtained by repeatedly performing the process of supplying 3DMAS as an Si precursor source to the substrate and the purging process, are shown in FIG. 8.

As illustrated in the results of FIG. 8, in the case of the “Zr” thin film, as temperature was increased from a temperature of about 290° C., thermal decomposition of the precursor source was performed quickly. As such, the deposition thickness rapidly increased due to the thermal decomposition. In the case of the “Zr+Si” thin film that was obtained by supplying a small amount of the Si precursor source after the Zr precursor source was supplied, thermal decomposition of the Zr source was suppressed, and the deposition thickness was marginally increased up to a temperature of about 330° C. 3DMAS, as the Si precursor source having a substantially high thermal decomposition temperature and a substantially strong thermal decomposition characteristic, was supplied after TEMAZ (the Zr precursor source) was supplied so that the thermal decomposition temperature of the Zr precursor source was increased up to about 50° C. even if high-temperature deposition was performed.

### Evaluative Example 3

FIG. 9 is a graph showing the result of measurements performed by a thermogravimetric differential thermal analyzer (TG-DTA) so as to evaluate thermal decomposition characteristics of Zr precursors that may be used in the method of FIG. 1.

For the measurements shown in FIG. 9, the Zr precursors were heated at a set setting temperature for 1 hour, and then the mass of a residual, which was not volatilized and which remained, was measured by using the TG-DTA so as to calculate a decomposition rate. According to the result shown in FIG. 9, for example, TEMAZ was thermally decomposed up to about 120° C. and maintained in a stable state.

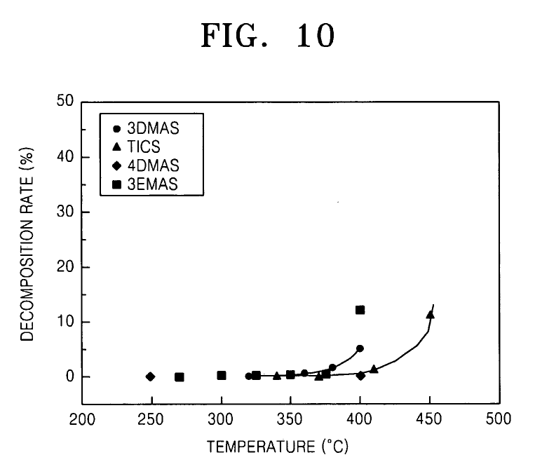

FIG. 10 is a graph showing a result of measuring performed by a TG-DTA so as to evaluate thermal decomposition characteristics of Si precursors that may be used in the method of FIG. 1.

For the measurement shown in FIG. 10, the Si precursors were heated at a set setting temperature for 1 hour, and then the mass of a residual, which was not volatilized and which remained, was measured by using the TG-DTA so as to calculate a decomposition rate. According to the result shown in FIG. 10, for example, 3DMAS was thermally decomposed up to about 320° C. and maintained in a stable state.

According to the results shown in FIGS. 9 and 10, if the dielectric thin film was formed by using ALD, for example, in order to reinforce the thermal stability of TEMAZ as the Zr precursor source, TEMAZ and 3DMAS were simultaneously supplied while an ALD process was performed to deposit the dielectric thin film or TEMAZ was first supplied and then 3DMAS was supplied, so that 3DMAS having a strong thermal decomposition characteristic was bonded to a portion having a weak thermal decomposition characteristic of a chemical adsorption layer of TEMAZ formed on the substrate and a chemically and stably bonded state was achieved.

While the inventive concept has been particularly shown and described with reference to example embodiments thereof, it will be understood that various changes in form and details may be made therein without departing from the spirit and scope of the following claims.

1. A method of forming a dielectric thin film of a semiconductor device, the method comprising:
supplying a first nuclear atom precursor source and a second nuclear atom precursor source having different thermal decomposition temperatures to a substrate;
forming a chemical adsorption layer including first nuclear atoms and second nuclear atoms on the substrate, wherein the first nuclear atoms are from the first nuclear atom precursor source and the second nuclear atoms are from the second nuclear atom precursor source;
supplying a reactant having oxygen atoms to the substrate on which the chemical adsorption layer is formed; and
forming an atomic layer including an oxide of the first nuclear atoms and the second nuclear atoms using the reactant having the oxygen atoms.

2. The method of claim 1, wherein forming the chemical adsorption layer includes simultaneously supplying the first nuclear atom precursor source and the second nuclear atom precursor source to the substrate.

3. The method of claim 1, wherein the first nuclear atom precursor source has a first thermal decomposition temperature, and the second nuclear atom precursor source has a second thermal decomposition temperature that is higher than the first thermal decomposition temperature.

4. The method of claim 3, wherein forming the chemical adsorption layer includes sequentially supplying the first nuclear atom precursor source and the second nuclear atom precursor source to the substrate.

5. The method of claim 4, wherein forming the chemical adsorption layer includes consecutively supplying the first nuclear atom precursor and the second nuclear atom precursor to the substrate.

6. The method of claim 1, wherein the chemical adsorption layer includes a first chemical adsorption layer having the first nuclear atoms contained in the first nuclear atom precursor source and a second chemical adsorption layer having the second nuclear atoms contained in the second nuclear atom precursor source.

7. The method of claim 1, wherein the first nuclear atoms of the first nuclear atom precursor source and the second nuclear atoms of the second nuclear atom precursor source are the same.

8. The method of claim 7, wherein the first nuclear atoms of the first nuclear atom precursor source and the second nuclear atoms of the second nuclear atom precursor source includes at least one selected from the group consisting of zirconium (Zr), hafnium (Hf), titanium (Ti), lanthanum (La), and silicon (Si) and combinations thereof.

9. The method of claim 1, wherein the first nuclear atoms of the first nuclear atom precursor source and the second nuclear atoms of the second nuclear atom precursor source are different.

10. The method of claim 9, wherein the first nuclear atoms of the first nuclear atom precursor source include at least one selected from the group consisting of Zr, Hf, Ti, La and combinations thereof, and
the second nuclear atoms of the second nuclear atom precursor source include at least one selected from a group consisting of Si, Ti and combinations thereof.

11. The method of claim 1, wherein the dielectric film is one selected from the group consisting of a zirconium (Zr) oxide film doped with silicon (Si), a zirconium (Zr) oxide film doped with titanium (Ti), an hafnium (Hf) oxide film doped with silicon (Si), an hafnium (Hf) oxide film doped with titanium (Ti), a titanium (Ti) oxide film doped with silicon (Si) and a lanthanum (La) oxide film doped with silicon (Si).

12. The method of claim 1, wherein the reactant having the oxygen atoms includes at least one gas selected from the group consisting of H₂O, H₂O₂, O₃, O₂, N₂O and combinations thereof.

13. The method of claim 1, wherein forming the chemical adsorption layer and forming the atomic layer are alternately repeated until the dielectric thin film is formed on the substrate to a desired thickness.

14. The method of claim 1, wherein a temperature of the substrate is about 100° C. to about 550° C.

15. The method of claim 1, wherein the first nuclear atom precursor source and the second nuclear atom precursor source are supplied to the substrate in a flow ratio of about 1:1 or less.

16. The method of claim 1, wherein the dielectric thin film is formed by performing atomic layer deposition (ALD) process.

17. The method of claim 1, wherein forming the atomic layer includes generating a plasma such that the first nuclear atoms and the second nuclear atoms react with the reactant having the oxygen atoms.

18. A method of manufacturing a capacitor, comprising:
forming a lower electrode on a substrate;
forming the dielectric thin film according to claim 1 on the lower electrode;
performing a heat treatment on the dielectric thin film; and
forming an upper electrode on the dielectric thin film.

19-37. (canceled)
